(19) United States
(12) Patent Application Publication
(10) Pub. No.: US 2014/0261607 A1
(43) Pub. Date: Sep. 18, 2014

(54) Thermoelectric Module with Flexible Connector

(71) Applicant: GMZ Energy, Inc., Waltham, MA (US)

(72) Inventors: Yanliang Zhang, Framingham, MA (US); Xiaowei Wang, Waltham, MA (US); Gang Chen, Carlisle, MA (US); Jonathan D'Angelo, Somerville, MA (US); Bed Poudel, Brighton, MA (US)

(73) Assignee: GMZ Energy, Inc., Waltham, MA (US)

(21) Appl. No.: 14/209,181

(22) Filed: Mar. 13, 2014

Related U.S. Application Data
(60) Provisional application No. 61/781,177, filed on Mar. 14, 2013.
(60) Provisional application No. 61/818,990, filed on May 3, 2013.

(51) Int. Cl. H01L 35/32; H01L 35/34

(52) U.S. Cl. CPC H01L 35/32; H01L 35/34
USPC 136/205; 29/592.1; 136/242; 136/201

(57) ABSTRACT

A thermoelectric power generating module incorporates compliance into the module using a three-dimensional flexible connector. The flexible connector may relieve thermal stress and improve reliability for thermoelectric modules. In addition, the connector may provide a buffer layer (e.g., cushion) to damp mechanical vibrations. In further embodiments, a thermal interface structure for a thermoelectric device includes a thermally conductive body comprising a first compliant surface for directly interfacing with a first component of the thermoelectric device and a second compliant surface, opposite the first surface, for directly interfacing with a second component of the thermoelectric device.

### RELATED APPLICATIONS

This application claims the benefit of priority to U.S. Provisional Application Nos. 61/781,177, filed Mar. 14, 2013, and 61/818,990, filed May 3, 2013, the entire contents of both of which are incorporated herein by reference.

### BACKGROUND

Thermoelectric converters, such as solar thermoelectric converters are known in the art. These converters rely upon the Seebeck effect to convert temperature differences into electricity. A portion of the thermoelectric converter may be directly or indirectly heated by a heat source to create the necessary temperature difference. The efficiency of the energy conversion depends upon the temperature difference across the thermoelectric converter. Greater temperature differences allow for greater conversion efficiency.

### SUMMARY

Various embodiments include a thermoelectric power generator module comprising a plurality of thermoelectric elements, each having a first side adapted to be at a first temperature and a second side adapted to be at a second temperature different than the first temperature when the module is in use, and a flexible connector that electrically connects the first sides of at least two thermoelectric elements. In various embodiments, the flexible connector may provide thermal strain relief and vibration damping to the thermoelectric elements.

Further embodiments include a flexible connector for a thermoelectric generator and methods of fabricating a thermoelectric power generator module having a flexible connector.

### BRIEF DESCRIPTION OF THE DRAWINGS

The accompanying drawings, which are incorporated herein and constitute part of this specification, illustrate exemplary embodiments of the invention, and together with the general description given above and the detailed description given below, serve to explain the features of the invention.

FIG. 1A is a schematic illustration of a thermoelectric power generator (TEG) module having a flexible connector according to one embodiment.

FIG. 1B is a side cross-sectional view of the flexible connector of FIG. 1A.

FIG. 1C is a perspective view of a compliant portion of a flexible connector that is a three-dimensional wire mesh.

FIG. 2A is a schematic illustration of a thermoelectric converter and a flexible connector including a compliant portion comprising an array of aligned wires.

FIG. 2B is a top view of the flexible connector of FIG. 2A.

FIG. 2C is a side view of the flexible connector of FIG. 2A.

FIG. 2D is a top view of a flexible connector including a compliant portion comprising an array of aligned wires having a generally circular cross-section.

FIG. 3 is a schematic illustration of a thermoelectric converter and a flexible connector including a compliant portion comprising at least one angled member.

FIG. 4 is a schematic illustration of a thermoelectric converter and a flexible connector including a compliant portion comprising a curved member.

FIG. 5 schematically illustrates a flexible connector including a compliant portion comprising an array of hollow hemispherically-shaped shells.

FIG. 6 schematically illustrates a flexible connector comprising a header having a bent portion to enable relative movement between a pair of thermoelectric legs connected to the header.

FIG. 7 illustrates a thermal interface structure comprising a metal foam.

FIG. 8A schematically illustrates a thermal interface structure having compliant wire arrays on two-sides of the connector.

FIG. 8B schematically illustrates a thermoelectric unicouple device having thermal interface structures with two-sided compliance directly interfacing each leg.

FIGS. 9A-9B schematically illustrate a cascaded thermoelectric device formed using a thermal interface structure with two-sided compliance.

FIGS. 10A-C schematically illustrate a thermoelectric device having a thermal interface structure between a surface of a thermoelectric module and a cover of the device.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

Multiple methods exist for generating electricity from heat energy. Various embodiments may include thermoelectric conversion elements. Thermoelectric conversion relies on the Seebeck effect to convert temperature differences into electricity. Thermoelectric converters operate more efficiently under greater temperature differences.

For example, solar thermoelectric generators include solar radiation absorbers that transfer solar energy to the high-temperature sides of thermoelectric converters such that a temperature differential is achieved across the thermoelectric converters that may be converted to electricity. Examples of this type of device are disclosed in U.S. Published Patent Application No. 2012/0160290, published on Jun. 28, 2012, the entire contents of which are incorporated herein by reference for all purposes. In addition to solar energy, various other heat sources may be used to provide a temperature difference across thermoelectric conversion elements, such as, for example, a hot fluid flow stream, boiler heat, automobile exhaust, industrial waste heat, etc. A heat exchanger may be used to transfer heat from the flow stream to a first side (i.e., the “hot” side) of the thermoelectric conversion elements.

In many of these systems, the temperature at the “hot” side of the thermoelectric element may be relatively high, such as 400° C. or more (e.g., ≧600° C., such as 600-800° C.). Furthermore, the temperature differential between the “hot” and “cold” sides of the elements may also be quite large, such as up to about 500° C. or more. At these temperatures and temperature differentials, thermal stress is a key challenge for thermoelectric generator reliability.

Various embodiments include a thermoelectric power generating module that incorporates compliance into the module using a flexible connector. The flexible connector may relieve thermal stress and improve reliability for thermoelectric modules. In addition, the connector may provide a buffer layer (e.g., cushion) to damp mechanical vibrations.

FIG. 1A is a schematic cross sectional side view of a thermoelectric generator (TEG) module 100 that generates electric power from a temperature differential between a “hot” side 101 and a “cold” side 103 of the module 100. Thermoelectric converters, such as the converter 106 depicted in FIG. 1A, can generate electricity when a sufficient temperature differential is established across the converter 106. The temperature differential may be provided by a heat source in thermal contact with the “hot” side 101 of the module 100. The heat source may be any suitable source of thermal energy, such as solar radiation, hot gas from a combustion reaction (e.g., boiler heat), waste heat, etc. To maintain the temperature differential across the module 100, the “cold” side 103 of the module 100 may be in thermal contact with a heat sink, which may be, for example, a thermally-conductive (e.g., metallic) heat spreader, a cooling fluid, or the ambient environment.

In some embodiments, a thermoelectric converter element 106 comprises multiple pairs (couples) of a p-type thermoelectric material leg 105A and an n-type thermoelectric material leg 105B. Each pair of legs 105A, 105B are thermally and electrically coupled at one end, e.g., to form a junction such as a pn junction or p-metal-n junction. The junction can be a header 107 made of an electrically and thermally conductive material, such as a metal. The junction can be coupled to an electrical isolator 113, which may be a thermally-conductive dielectric material, as shown in FIG. 1A. The electrical isolator 113 may comprise a thermally conductive member that absorbs thermal energy from the “hot” side 101 of the module, and transfers the thermal energy through the header 107 to a first (hot) side 104 of the thermoelectric legs 105A, 105B. The electrical isolator 113 may also provide mechanical support for the thermoelectric converters 106. The electrical isolator 113 may be electrically insulated from the header(s) 107, e.g., all or portion(s) of the isolator 113 contacting the header(s) 107 may be made of a thermally conductive, electrically insulating material, and/or the isolator 113 may be separated from the header(s) 107 by a layer of thermally conductive, electrically insulating material (not shown).

Electrical connectors 109 may be connected to the second (cold) ends 102 of the thermoelectric legs 105A, 105B. The electrical connectors 109 may be made of a thermally and electrically conductive material, such as metal, and may be flexible connectors as described below. The connectors 109 may be laterally offset from the header connectors 107 such that for each pair of legs 105A, 105B connected to a header 107, one leg 105A (e.g., a p-type leg) of the pair contacts a first connector 109, and the other leg 105B (e.g., an n-type leg) of the pair contacts a second connector 109. As shown, this configuration may be repeated for multiple pairs of thermoelectric legs 105A, 105B to produce a series connected electrical path. Electrically conductive leads 117 are also depicted, which can provide appropriate electrical coupling within and/or between thermoelectric converters 106, and can be used to extract electrical energy generated by the converters 106.

The arrangements of the p-type and n-type thermoelectric legs 105A, 105B can vary in any manner that results in an operational thermoelectric generator module 100. For example, as shown in FIG. 1A, the connectors 109 are oriented parallel to and laterally offset from the headers 107 to provide a series-connected one-dimensional TEG module 100. Alternatively, at least a portion of the connectors 109 may be oriented in a generally orthogonal direction relative to the headers 107 (i.e., into and out of the page in FIG. 1A) to provide a two-dimensional array of series- and/or parallel-connected thermoelectric converters 106.

As shown in FIG. 1A, the connectors 109 are coupled to an electrical isolator 111 to provide electrical isolation and supporting structure for the thermoelectric module 100. The electrical isolator 111 may be made of a thermally-conductive dielectric material, and may be a thermally-conductive ceramic. The electrical isolator 111 may be electrically insulated from the connectors 109, e.g., all or portion(s) of the isolator 111 contacting the connector(s) 109 may be made of a thermally conductive, electrically insulating material, and/or the electrical isolator 111 may be separated from the connector(s) 109 by a layer of thermally conductive, electrically insulating material (not shown).

In various embodiments, the temperature at the electrical isolator 113, headers 107 and the “hot” sides 104 of the thermoelectric elements 105A, 105B may be 400° C. or more (e.g., 500° C. or more), such as 600-700° C. The temperature at the electrical isolator 111, connectors 109 and the “cold” sides of the thermoelectric elements 105A, 105B may be 200° C. or less, such as 150° C. or less (e.g., ≦100° C., such as 20-100° C.). The temperature differential between these “hot” side and “cold” side elements may be 250° C. or more, such as 500° C. or more (e.g. 200-680° C.).

As discussed above, thermal stress is a key challenge in the reliability of thermoelectric generator modules. This is particularly challenging when one or more sides of the module are at high temperature (e.g., ≧400° C.) and/or when there is a large temperature gradient between the hot and cold sides of the module. Mechanical vibrations of the module can also negatively affect the performance of the module, and can be problematic when the thermoelectric converters are attached to a surface 111 that experiences vibrations. As shown in FIGS. 1A-1C a flexible connector 109 may provide electrical connection between thermoelectric converter legs 105. The flexible connector 109 may be configured to provide good electrical contact with the adjacent surface 102 of the thermoelectric converter legs 105A, 105B while also including sufficient compliance to relieve thermal stress and provide thermal strain relief under varying thermal conditions. The flexible connector 109 may also provide a buffer or cushion to damp mechanical vibrations. In the embodiment of FIG. 1A, the flexible connectors 109 are shown proximate the “cold” side 103 of the module 100, while conventional connectors (i.e., headers 107) are used proximate the “hot” side 101 of the module 100. In other embodiments, a flexible connector 109 may be used on the “hot” side 101 and a conventional (i.e., non-flexible) connector may be used on the “cold” side 103. In further embodiments, flexible connectors 109 may be used on both the hot and cold sides 101, 103 of the module 100.

The flexible connector 109 may have a plurality of first contact members 110, such as pair of first contact members 110 as shown in FIGS. 1A-1B. The first contact members 110 may interface with the ends 102 of the thermoelectric legs 105A, 105B and may provide good thermal and electrical contact with the respective thermoelectric legs 105A, 105B. The size and shape of the first contact members 110 may substantially correspond to the size and shape of the thermoelectric legs 105A, 105B. For example, the surface area of each first contact member 110 may be between about 0.25 and 25 mm² to approximately match the 0.25-25 mm² surface area of the adjacent thermoelectric leg 105A, 105B. The flexible connector 109 may also have a second contact member 112 opposite the first contact members 110 that may be thermally and mechanically coupled to the electrical isolator 111. The contact member 112 is preferably electrically and thermally conductive. A compliant portion 114 may extend between each of the first contact members 110 and the second contact member 112.

The compliant portion 114 of the flexible connectors described herein may comprise any suitable flexible, compliant material and/or structure, such as a mesh, felt, foam (see FIG. 7), wire array, protrusion, spring member, elastomer, etc. The compliant portion 114 may be electrically and thermally conductive, and may be made from any suitable material(s), such as a metal material, including metal alloys, a polymeric material, as well as various combinations and composites of the same. The compliant portion 114 is flexible in that the compliant portion 114 forms a non-rigid deformable structure having a first interfacing surface (which may be directly or indirectly mechanically coupled to a thermoelectric leg) and a second interfacing surface (which may be directly or indirectly mechanically coupled to a support structure), where the first interfacing surface and the second interfacing surface are displaceable relative to each other along at least one dimension within a given range (e.g., up to about 2 mm, such as up to about 1 mm, up to about 0.5 mm, up to about 0.1 mm, up to about 0.01 mm, or up to about 1 micron) while maintaining thermal and electrical conductivity between the first and second interfacing surfaces.

As shown in FIGS. 1A-1B, the compliant portion 114 interfaces at a first end with the first contact member 110 and at a second end with the second contact member 112. In other embodiments, one or both of the first contact member 110 and the second contact member 112 may be eliminated, and the compliant portion may interface directly with a thermoelectric leg 105A, 105B at its first end, and/or with the electrical isolator 111 (e.g., with a bonding pad or other conductive material on the electrical isolator 111) at its second end.

The compliant portion 114 may be metal mesh, such as a three dimensional mesh (e.g., flexible cage) as shown in FIG. 1C. A first interfacing surface 116 of the compliant portion 114 may be thermally and electrically coupled to an end 102 of a thermoelectric leg 105A, 105B and a second interfacing surface 118 of the compliant portion 114 may be thermally and electrically coupled to the electrical isolator/support structure 111 of the module 100, as shown in FIG. 1A. The compliant portion 114 may be flexible in at least one dimension, such as in two dimensions, and preferably in three-dimensions. As shown in FIG. 1C, for example, the compliant portion 114 may expand and contract in the y-direction (i.e., increase/decrease the separation between the first and second interfacing surfaces 116, 118), and may also flex in the x- and z-directions (i.e., all or portions of the first interfacing surface 116 may move with respect to the second interfacing surface 118 in the direction(s) of the x- and/or z-axes). The compliant portion 114 may also support torsional flexing, such as rotational displacement of the first interfacing surface 116 relative to the second interfacing surface 118 with respect to the y-axis, as well as tilting or bending displacement in and out of the x-z plane. In an alternative embodiment, the compliant portion may comprise a compliant electrically and thermally conductive metal felt or foam, such as a nickel, copper, etc., foam or felt.

A second embodiment of a flexible connector 209 for a thermoelectric converter 106 is shown in FIGS. 2A-D. FIG. 2A illustrates a unicouple 206 (i.e., one basic unit of a thermoelectric converter) that includes a pair of p-type and n-type thermoelectric legs 105A, 105B connected by a header 107, as described above in connection with FIG. 1A. A flexible connector 209 in this embodiment includes a compliant portion 214 in the form of an array of wires 215 (i.e., elongated rods). The wires 215 may be aligned generally parallel to one another, and may be secured at one end to a connector base 212. The wires 215 may be aligned with their long axes in the y-direction parallel to direction extending from the legs to the connector base. The tips of the wires 215 form an interfacing surface 216 that may directly contact an end of a thermoelectric leg 105A, 105B, as shown in FIG. 2A. Alternatively, the tips of the wires 215 may be bonded to a separate contact member (not shown) that is coupled to the thermoelectric leg.

The array of wires 215 may be configured to elastically deform, such as by bending, contracting, stretching, and/or twisting with respect to the connector base 212 and/or the end of the thermoelectric leg 105A, 105B, in response to a relative displacement between the connector base 212 and the thermoelectric leg 105A, 105B, which may be the result of thermally-induced stress and/or system vibrations. For example, the wires may deform in the y-direction and optionally in the x and/or z-directions in addition to the y-direction. The array of wires 215 may provide strain relief and/or vibration damping between the connector base 212 and the thermoelectric leg 105A, 105B while maintaining a continuous electrical and thermal connection between these components.

The wires 215 may be made any thermally and electrically conductive material. In embodiments, the wires 215 may be metal wires and may comprise, for instance, copper, tin, aluminum, or other suitable metals or metal alloys. In embodiments, the wire array may be made by dicing a metal sheet, such as a copper sheet, to produce an array of aligned metal wires (e.g., a “forest” of vertically-aligned wire “trees”) on a supporting substrate, as shown in FIG. 2C. The connector base 212 may also be made of a thermally and electrically conductive material, which may be the same material or a different material than the wires. In embodiments, the wires 215 may be integral with the base 212, as shown in FIG. 2C. In other embodiments, the wires 215 may be formed separately from the base 212 and bonded to the base 212 using any suitable technique. In some embodiments, the connector base 212 may be secured to a TEG module support structure/heat spreader, such as electrical isolator/support structure 111 in FIG. 1A. In the embodiment of FIG. 2A, the connector base 212 may be secured to an electrically insulating substrate 213, such as a ceramic substrate, and the insulating substrate 213 may be secured to the TEG module support structure.

In embodiments, the connector base 212 and insulating substrate 213 may be formed using a direct bonded copper (DBC) technique. Direct bonded copper (DBC) substrates include a ceramic tile (e.g., alumina, aluminum nitride, beryllium oxide, etc.) with a sheet of copper bonded to one or both sides by a high-temperature oxidation process (e.g., heating the copper and substrate in controlled atmosphere of nitrogen and about 30 ppm oxygen to form a copper-oxygen eutectic which bonds to both the copper layer and the oxide(s) of the substrate layer). DBC substrates are often used in power modules due to their high thermal conductivity. The copper surface layer may be patterned prior to firing and/or portions of the copper layer may be removed after firing (e.g., etched using printed circuit board technology) to form one or more connector bases 212 on an insulating substrate 213. The copper surface layer may be formed into any desired pattern for electrically connecting a plurality of thermoelectric converters 106 in a series and/or parallel circuit configuration. For example, as shown in FIG. 2D, the connector base 212 may electrically connect p- and n-type legs of two different thermoelectric converters 106 in series. In some embodiments, a second copper sheet may be bonded to the bottom surface of the insulating substrate 213, and the bottom copper layer may be bonded to a support structure/electrical isolator 111, such as via soldering.

FIGS. 2B and 2C are top and side views, respectively, of the flexible connector 209 of FIG. 2A. FIG. 2B illustrates the compliant portion 214 comprised of an array of wires 215. The wires 215 have a generally square cross-sectional shape in this embodiment, but may have any suitable cross sectional shape, such as a circular cross-section (as shown in FIG. 2D), an oval cross section, a rectangular or other polygonal cross section, etc. The wires 215 may have a generally uniform cross-sectional area along their length or may have a varying cross-sectional area along their length, such as a tapered cross section. The cross-sectional shapes and/or cross-sectional areas of the wires 215 may vary within an array. In addition, although the wires 215 in FIG. 2 are shown as having an ordered, uniformly-spaced arrangement, in other embodiments, the wires 215 may have non-uniform spacing (e.g., more tightly-packed in the center and sparser in the periphery, or vice versa) and/or may be arranged in a random, non-ordered manner.

The dimensions and spacing of the wires 215 may be selected to optimize the heat flux/thermal conductance and electrical conductivity through the wires 215. In one embodiment, the dimensions of the wires 215 (e.g., length, l, and width, w, in FIG. 2B; diameter, d, in FIG. 2D) may be between about 10-300 microns (e.g., 100-200 microns, such as about 100 microns), and the spacing, s, between wires may be between about 50-500 microns (e.g., 100-300 microns, such as about 250 microns). The overall dimensions (e.g., length, L and width, W) of the compliant portion 214 may be substantially equal to the dimensions of the thermoelectric leg 105A, 105B that the compliant portion 214 interfaces, and may be between about 0.5 and 5 mm (e.g., 0.5-1.5 mm) such as about 1 mm, with an area of about 0.25 and 25 mm². The height, h, of the wires 215 may be between about 0.01 and 5 mm (e.g., 0.5-1.5 mm) such as about 1 mm, as shown in the side view of FIG. 2C.

FIG. 2D is a top view of a connector 209 that includes two compliant portions 214 that may form thermal and electrical contact with the respective ends of a p-type and an n-type thermoelectric leg 105A, 105B (illustrated in phantom). The compliant portions 214 are electrically connected by a conductive connector base 212. In this manner, respective legs 105A, 105B of pairs of thermoelectric converters 106 may be electrically connected in series. The connector base 212 may be formed by patterning a conductive material on an insulating substrate 213, such as using a direct bonded copper (DBC) technique as described above. A patterned DBC connector may enable dense packing of thermoelectric converters 106 (i.e., a high packing factor) in a TEG module while minimizing unintended electrical shortages between converters 106. The compliant portions 214 between each of the legs 105A, 105B and the connector base 212 may significantly reduce the thermal stress within the thermoelectric converter devices and improve device reliability.

A third embodiment of a flexible connector 309 for a unicouple 106 is shown in FIG. 3. FIG. 3 illustrates a unicouple 206 including a pair of p-type and n-type thermoelectric legs 105A, 105B connected by a header 107, as described above. A flexible connector 309 in this embodiment includes a compliant portion 314 in the form of one or more angled members 315. The angled member 315 may be a rod, tab or other projection that is secured at one end to a connector base 312. The opposite end of the angled member 315 is coupled to an end of a thermoelectric leg 105A, 105B. The angled member 315 may be coupled to a contact member 310 that contacts the end of the thermoelectric leg 105A, 105B, as shown in FIG. 3. Alternatively, the angled member 315 may be in direct contact with the respective thermoelectric leg 105A, 105B.

The one or more angled member(s) 315 may be made of any thermally and electrically conductive material, and may provide a thermal and electrical connection between a thermoelectric leg 105A, 105B and the connector base 312. In embodiments, the angled member(s) 315 may be made of a metal material and may comprise, for instance, copper, tin, aluminum, or other suitable metals or metal alloys. The one or more angled member(s) 315 may function as a spring contact between the connector base 312 and the thermoelectric leg 105A, 105B. In other words, the one or more angled member(s) 315 may be configured to elastically deform, such as by bending and/or articulating with respect to the connector base 312 and/or the end of the thermoelectric leg 105A, 105B, in response to a relative displacement between the connector base 312 and the thermoelectric leg 105A, 105B, which may be the result of thermally-induced stress and/or system vibrations. The one or more angled member(s) 312 may provide strain relief and/or vibration damping between the connector base 312 and the thermoelectric leg 105A, 105B while maintaining a continuous electrical and thermal connection between these components.

The connector base 312 may also be made of a thermally and electrically conductive material, which may be the same material or a different material than the at least one angled member 315. In embodiments, the connector base 312 may be integral with the angled member 315. In other embodiments, angled member 315 may be a separate component that is bonded to the connector base 312. In some embodiments, the connector base 312 may be secured to a TEG module support structure/electrical isolator, such as electrical isolator 111 in FIG. 1A. In the embodiment of FIG. 3, the connector base 312 may be secured to an electrically insulating substrate 313, such as a ceramic substrate, and the insulating substrate 313 may be secured to the TEG module support structure. The insulating substrate 313, the connector base 312, and optionally the one or more angled member(s) 315 may be formed by a direct bonded copper (DBC) technique, as described above.

A fourth embodiment of a flexible connector 409 for a unicouple 206 is shown in FIG. 4. FIG. 4 illustrates a unicouple 206 including a pair of p-type and n-type thermoelectric legs 105A, 105B connected by a header 107, as described above. A flexible connector 409 in this embodiment includes a compliant portion 414 in the form of a curved contact member 415. The curved contact member 415 may be a generally hemispherically-shaped hollow shell, as shown in cross-section in FIG. 4. A base of the curved contact member 415 (e.g., shell) may be fixed to a connector base 412, and the opposite end of the curved contact member 415 may contact an end of a thermoelectric leg 105A, 105B. The curved contact member 415 may be in direct contact with the respective thermoelectric leg 105A, 105B, as shown in FIG. 4. Alternatively, the curved contact member 415 may be coupled to a separate (e.g., planar) contact member (not shown) that contacts the end of the thermoelectric leg 105A, 105B.

The curved contact member 415, such as a hollow generally hemispherically-shaped shell, may be made of any thermally and electrically conductive material, and may provide a thermal and electrical connection between a thermoelectric leg 105A, 105B and the connector base 412. In embodiments, the curved contact member 415 may be made of a metal material and may comprise, for instance, copper, tin, aluminum, or other suitable metals or metal alloys. The curved contact member 415 (e.g., shell) may have a diameter between about 10 microns and 10 mm, such as 0.5-5 mm. The curved contact member 415 may be configured to elastically deform (e.g., in the y-direction) in response to a relative movement between the connector base 412 and the thermoelectric leg 105A, 105B, which may be the result of thermally-induced stress and/or system vibrations. The curved contact member 415 may provide strain relief and/or vibration damping between the connector base 412 and the thermoelectric leg 105A, 105B while maintaining a continuous electrical and thermal connection between these components.

The connector base 412 may also be made of a thermally and electrically conductive material, which may be the same material or a different material than the curved connector member 415. In embodiments, the connector base 412 may be integral with the curved contact member 415. In other embodiments, the curved contact member 413 may be a separate component that is bonded to the connector base 412. In some embodiments, the connector base 412 may be secured to a TEG module support structure/electrical isolator, such as electrical isolator 111 in FIG. 1A. In the embodiment of FIG. 4, the connector base 412 may be secured to an electrically insulating substrate 413, such as a ceramic substrate, and the insulating substrate 413 may be secured to the TEG module support structure. The insulating substrate 413, the connector base 412, and optionally the curved contact member 415 may be formed by a direct bonded copper (DBC) technique, as described above.

Another embodiment of a flexible connector 509 for a thermoelectric converter is shown in FIG. 5. In this embodiment, the compliant portion 514 is a plurality of curved contact members 515, such as generally hemispherically-shaped hollow shells, of a thermally and electrically conductive material (e.g., metal, such as copper). The curved contact members 515 (e.g., hollow shells) may each have a diameter between about 10-300 microns (e.g., 100-200 microns, such as about 100 microns), and may be spaced by about 50-500 microns (e.g., 100-300 microns, such as about 250 microns) from one another. The curved contact members 515 may be secured on one end to a connector base 512. A thermoelectric leg 105, shown in phantom in FIG. 5, may contact the upper surfaces of the curved contact members 515. The plurality of curved contact members 515 (e.g., hollow shells) may provide an elastically deformable contact surface that provides strain relief and/or vibration damping between the connector base 512 and the thermoelectric leg 105 while maintaining a continuous electrical and thermal connection between these components In some embodiments, the plurality of curved contact members 515 in the form of hollow shells may function similar to “bubble wrap.” Thus, the members 515 in FIG. 5 differ from each member 415 in FIG. 4 in that plural members 515 support one leg 105, while a single member 415 supports a single respective leg 105. Thus, members 515 have a smaller size than member 415.

FIG. 6 illustrates an embodiment of a connector 607 between a pair of thermoelectric legs 105A, 105B. The connector 607 may be made of a thermally and electrically conductive material. The connector 607 may be located on the “hot” side of a TEG module and may comprise a header that contacts the thermal absorber 113 as shown in FIG. 1A. Alternatively, the connector 607 may be located on the “cold” side of the TEG module, and may contact a support structure/electrical isolator as shown in FIG. 1A. In this embodiment, the connector 607 includes a compliant portion in the form of a bent portion 614 (e.g., a dip) that provides an elastically deformable region that allows the thermoelectric legs 105A, 105B to be displaced relative to one another (e.g., move towards or away from one another and/or flex relative to each other, such as in the x and/or z-direction) while still maintaining a thermal and electrical connection between the legs 105A, 105B. The bent portion 614 in the connector 607 (e.g., header) may provide strain relief and/or vibration damping between the respective thermoelectric legs 105A, 105B.

Thermal Interface Structure for Thermoelectric Devices

Various embodiments include a thermal interface structure for a thermoelectric device. The thermal interface structure may be provided between two or more components of a thermoelectric device and may include at least one compliant portion to relieve thermal stress and provide thermal strain relief for the components under varying thermal conditions. The thermal interface structure may be thermally conductive and optionally electrically conductive, such as the connectors of the various embodiments described above. The thermal interface structure may be or may include a metal foam, mesh, felt, etc., as described above. FIG. 7 illustrates one embodiment of a thermal interface structure 709 that is formed of a metal foam. The foam may be formed of a metal such as copper, nickel, or aluminum, including various combinations and alloys of these materials.

The thermal interface structure 709 may be self-supporting and may also be compliant on two-sides of the structure 709. As used herein, two-sided compliance means that compliant portions on two opposing sides of the structure 709 directly interface (with or without a bonding agent, such as a solder or brazing material) with two different components of the thermoelectric device. A two-sided compliant structure is distinguished from a one-sided compliant structure, such as the flexible connector 209 of FIG. 2A, for example, where a compliant portion 214 on one side of the connector 209 directly interfaces with the thermoelectric legs 105, but the opposing side of the connector 209 interfaces with the substrate 213 via a connector base 212 that is rigid and non-compliant. In the two-sided compliant interface structure 709 of FIG. 7, each of the interfacing surfaces of the structure 709 may be displaceable in at least one dimension, and preferably in two- or three-dimensions within a given range (e.g., up to about 2 mm, such as up to about 1 mm, up to about 0.5 mm, up to about 0.1 mm, up to about 0.01 mm, or up to about 1 micron, e.g., 0.5 μm to 2 mm) while maintaining thermal and preferably also electrical conductivity between the first and second interfacing surfaces. Thus, in various embodiments, each of the interfacing surfaces of the structure 709 may expand, contract, twist and/or bend in the x-, y- and z-directions to relieve thermal stress and provide thermal strain relief under varying thermal conditions. The thermal interface structure 709 having two-sided compliance may provide a suitable thermal, mechanical and optional electrical interface between different thermoelectric materials or dissimilar metals in a thermoelectric device, for example.

FIG. 8A illustrates an additional embodiment of a thermal interface structure 809 having two-sided compliance. In this embodiment, the thermal interface structure 809 includes a first compliant portion 815 in the form of a first array of wires (i.e., elongated rods) and a second compliant portion 817 in the form of a second array or wires (i.e., elongated rods). The wires may be secured at one end to a base portion 812 (e.g., a flat plate support) and may be aligned generally parallel to one another with their long axes in the y-direction. The tips of the wires in each array form an interfacing surface that may directly interface (with or without a bonding agent, such as a solder or brazing material) with two different components of the thermoelectric device. FIG. 8B illustrates a thermoelectric unicouple 806 with a pair of two-sided wire array thermal interface structures 809 provided between the (cold side) ends of a pair of thermoelectric legs 105A, 105B (i.e., a p-type and n-type leg, respectively) and respective electrically-conductive connectors 112. The opposing (hot side) ends of the legs 105A, 105B are connected by a header 107. The thermal interface structures 809 in this embodiment may be similar to the flexible connector 209 shown in FIGS. 2A-D, with the thermal interface structures 809 of FIG. 8A each having two separate wire arrays to provide two-sided compliance between the respective ends of each thermoelectric leg 105A, 105B and a connector 112, which may connect the unicouple 106 to an adjacent thermoelectric leg or to an electrical lead (not shown).

Each wire array 815, 817 of the thermal interface structure 809 may be configured to elastically deform, such as by bending, contracting, stretching, and/or twisting with respect to the base portion 812 and the component of the thermoelectric device with which the array interfaces in response to a relative displacement between the base portion 812 and component which may be the result of thermally-induced stress and/or system vibrations. For example, the wires may deform in the y-direction and optionally in the x and/or z-directions in addition to the y-direction. In the unicouple 106 of FIG. 8B, for example, each wire array may provide strain relief and/or vibration damping between the base portion 812 and the respective thermoelectric leg 105A, 105B or connector 112 while maintaining a continuous electrical and thermal connection between these components.

The wires of the arrays 815, 817 may be made of any thermally conductive material. In embodiments, the wires may be metal wires and may comprise, for instance, copper, tin, aluminum, or other suitable metals or metal alloys. The base portion 812 may be made from a thermally conductive material and may be the same or a different material than the wires. In embodiments where the thermal interface structure 809 provides an electrical as well as thermal connection between two components of a thermoelectric device, the wire arrays 815, 817 and base portion 812 may all be made of an electrically conductive material, such as one or more metal materials. In other embodiments, one or more of the wire arrays 815, 817 and base portion 812 may comprise an electrically insulating or non-conductive material to provide thermal coupling and electrical isolation between the components of the thermoelectric device.

A thermal interface structure having two-sided compliance may have any suitable structure in addition to the metal foam 709 and two-sided wire array 809 structures shown in FIGS. 7 and 8A-B, respectively. For example, the thermal interface structure may comprise a porous matrix, such as a porous graphite matrix, that may optionally include a filler material, such a metal or metal alloy filler. The filler material may comprise a bonding agent, such as a brazing material (e.g., a metal or metal alloy, such as silver, copper, a silver-copper based alloy, an aluminum alloy, a nickel alloy, a titanium alloy, etc.) that facilitates bonding of the interfacing surfaces of the structure to the adjacent components of the thermoelectric device. The filler material may also function to increase the thermal conductivity of the thermal interface structure and where the porous matrix comprises an electrically non-conductive or low-conductive material may increase the electrical conductivity of the structure.

A thermal interface structure as described herein may provide a compliant thermal and electrical interface between two or more thermoelectric legs in a segmented or cascaded design. FIGS. 9A and 9B illustrate an exemplary embodiment of a segmented or cascaded thermoelectric generator, where two or more different generators are coupled, each generator operating at a different temperature range. For instance, each p-n pair can be a stack of p-n pairs, each pair designed to work at a selected temperature. In some instances, segmented and/or cascaded configurations are adapted for use over a large temperature range so that appropriate thermoelectric materials are used in the temperature range in which they perform best.

As shown in FIG. 9A, a first pair of p-type and n-type legs 105A, 1051 are connected on one side of the legs 105A, 105B by a metal header 107. The first pair of legs 105A, 105B may exhibit high performance over a relatively higher temperature range, and thus may be referred to as the “hot side” legs. The opposing sides of the legs 105A, 105B may be directly interfaced by respective thermal interface structures 809A, 809B, each of which may be a self-supporting thermally and electrically conductive structure having two-sided compliance, as described above. As used herein, a “direct interface” means that a compliant interfacing surface of the thermal interface structure is coupled to the adjacent thermoelectric material leg, with or without a separate bonding agent (e.g., brazing material, solder, etc.), and without any rigid, non-compliant structure being located between the leg and the compliant surface of the thermal interface structure. In this embodiment, the thermal interface structures 809A, 809B comprise two-sided wire arrays, although other compliant interface structures, such as a metal foam, may also be utilized.

As shown in FIG. 9B, the thermal interface structures 809A, 809B directly interface with a second pair of p-type and n-type legs 905A, 905B. The second pair of legs 905A, 905B may have a higher performance over a relatively lower temperature range than the first pair of legs 105A, 105B, and may thus be referred to as the “cold side” legs. Each thermal interface structure 809A, 809B may conduct heat and electricity between the adjacent “hot side” and “cold side” legs while providing stress relief for both legs. In the embodiment of FIG. 9B, the lower temperature sides of the “cold side” legs 905A, 905B are coupled to a (non-compliant) electrical connector 112, although in other embodiments a flexible connector having one-sided or two-sided compliance may be utilized. In addition, although the segmented or cascaded design of FIGS. 9A-B illustrates a stack of two pairs of p- and n-type thermoelectric legs, in which the p-type stack contains hot side and cold side leg portions directly interfaced by a thermal interface structure, and the n-type stack contains hot side and cold side leg portions directly interfaced by a thermal interface structure, the stack may include more than two pairs of legs, with thermal interface structures 905A, 905B having two-sided compliance being located between each adjacent leg portion in the stack. The two-sided compliance may be advantageous for stress relief in a segmented or cascade design using thermoelectric elements comprised of different materials with dissimilar thermal properties (e.g., coefficients of thermal expansion) and operating over different temperature ranges. The thermal interface structure having two-sided compliance may provide a straightforward and cost-effective approach compared to conventional cascade design.

In a further embodiment, a thermal interface structure as described herein may provide a compliant thermal interface between a thermoelectric generator module and a cover of the module. FIG. 10A illustrates an example of a thermoelectric module 1001, which includes a plurality of thermoelectric generators that are electrically interconnected using suitable connectors. The top surface of the module 1001 may be defined by a plurality of electrically and thermally conductive headers 107, which may be coupled to the “hot” sides of the thermoelectric elements, or by electrical isolator(s) 113 (see FIG. 10A). Typically, a protective cover 1003, such as the cover shown in FIG. 10B, is provided over the module to protect the module components from oxidation and moisture especially at high temperature applications and optionally to provide electrical isolation. The cover 1003 may be made of or may include an insulating material, such as a ceramic material, to electrically isolate the module 1001 from the external environment. Alternatively, a conductive (e.g., metal) cover 1003 may be used if an electrical isolator 113 is used. The cover 1003 may be thermally conductive so as to channel thermal energy from the external environment to the “hot” side of the module 1001. Typically, the top surface of the module 1001 is bonded to the interior surface of the cover 1003 to maximize the thermal contact between the cover 1003 and the “hot” side of the module 1001. However, the inventor has discovered that at operating temperature, thermal stresses resulting from a mismatch in the coefficient of thermal expansion (CTE) between the cover 1003 and one or more components of the module 1001 may cause the module 1001 to separate from the cover 1003, and/or the relatively fragile thermoelectric material legs to break or separate from the adjacent metal connectors, resulting in poor performance or even failure of the module.

The inventor has discovered that the overall performance of a module may be improved by providing a thermal interface structure with two-sided compliance between the module 1001 and the module cover 1003. FIG. 10C is a partial cross-section schematic view of a module 1001 having a thermal interface structure 1006 between an outer (e.g., top) surface of the module and the interior surface of the cover 1003. In this embodiment, the top surface of the module is defined by a header 107 which is thermally and electrically coupled to a plurality of thermoelectric material legs 105A, 105B, and/or by an isolator 113. As described above, the cover 1003 may protect and electrically isolate the module 1001 from the external environment. The cover 1003 may be electrically insulating and thermally conductive, and may transfer thermal energy from an external heat source (e.g., a burner flame, automotive/industrial exhaust, solar radiation, etc.) through the cover 1003 to the “hot” side of the module 1001. A heat exchanger (not shown) may be thermally coupled to the cover 1003 to facilitate the transfer of heat from an external heat source through the cover 1003. The thermal interface structure 1006 may comprise any suitable interface structure having two-sided compliance, such as the metal foam shown in FIG. 7 or the two-sided wire array structure shown in FIGS. 8A-B. A soldering or brazing material may be used to couple the thermal interface structure 1006 to the cover 1003 and/or the module 1001, as described below.

The thermal interface structure may be designed to provide sufficient thermal conductance between the cover 1003 and the module 1001 while providing mechanical compliance between these components. While the thermal conductance between the cover 1003 and module 1001 via the thermal interface structure 1006 may not be as high as in the case where the cover 1003 is directly bonded to the top of the module 1001, the stress relief provided by the compliant thermal interface structure 1006 minimizes damage to the module 1001 from thermal effects and may improve the overall performance of the module 1001, including significantly improving module life time.

The thermal conductance through the thermal interface structure 1006 may also be increased by providing a bonding agent at the interface between the thermal interface structure 1006 and the cover 1003 and/or at the interface between the thermal interface structure 1006 and the module 1001. The bonding agent may be a brazing material 1005, as illustrated in FIG. 10C. Brazing is a technique for joining two materials using a filler material that is heated above its melting point and flows into the interface between the two materials via alloying or capillary action. The liquid brazing material is then cooled to join the two materials together. Brazing is typically performed at a temperature sufficient to melt the brazing material without melting the materials being joined (e.g., at a temperature above 450° C., such as 450-850° C.). The brazing material may be in the form of a solid rod, wire or perform that is positioned adjacent to the interface of the two materials, and may be held (i.e., pressed) against the interface as the brazing material is heated above its melting temperature. The liquefied brazing material “wicks” into the gap between the materials via alloying or capillary action to bond the materials. The brazing material may fill the pores at the interface between the thermal interface material 1006 and the adjacent material (e.g., within the pores of a foam material or between the wires in the case of a wire array), thereby increasing the thermal conductivity between the thermal interface material 1006 and the component to which it is bonded. Suitable brazing materials may include, for example, silver, copper, a silver-copper based alloy, an aluminum alloy, a nickel alloy, a titanium alloy, etc.

Where the thermal interface material 1006 is provided between a thermoelectric module 1001 and an electrically insulating cover 1003, the thermal interface material 1006 need not be electrically conductive. In addition to the thermal interface material 1006 between the module 1001 and the cover 1003, one or more additional flexible connectors/thermal interfaces structures having one-sided or two-sided compliance may be utilized within the module 1001, such as between the thermoelectric legs and header 107, between the legs and the “cold side” electrical connectors, and/or between legs in a segmented or cascaded design, as described above.

In various embodiments, the thermoelectric converters 105 may be made from a variety of bulk materials and/or nanostructures. The converters preferably comprise plural sets of two converter elements-one p-type and one n-type semiconductor converter post or leg which are electrically connected to form a p-n junction. The thermoelectric converter materials can comprise, but are not limited to, one of: half-Heuslers, Bi₂Te₃, Bi₂Te₃₋ₓSeₓ (n-type)/BiₓSe₂₋ₓTe₃ (p-type), SiGe (e.g., Si₈₀Ge₂₀), PbTe, skutterudites, Zn₃Sb₄, AgPbₘSbTe₂₊ₘBi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material. For example, see U.S. patent application Ser. No. 11/949,353 filed Dec. 3, 2007, which is incorporated herein by reference for all purposes, for a description of exemplary materials.

In preferred embodiments, the thermoelectric elements 105 comprise half-Heusler materials. Suitable half-Heusler materials and methods of fabricating half-Heusler thermoelectric elements are described in U.S. patent application Ser. No. 13/330,216 filed Dec. 19, 2011 and Ser. No. 13/719,96 filed Dec. 19, 2012, the entire contents of both of which are incorporated herein by reference for all purposes. Half-Heuslers (HHs) are intermetallic compounds which have great potential as high temperature thermoelectric materials for power generation. HHs are complex compounds: MCoSb (p-type) and MNiSn (n-type), where M can be Ti or Zr or Hfor combination of two or three of the elements. Sn and Sb can be substituted by Sn/Sb; Co and Ni by Ir and Pd. They form in cubic crystal structure with a F4/3m (No. 216) space group. These phases are semiconductors with 18 valence electron count (VEC) per unit cell and a narrow energy gap. The Fermi level is slightly above the top of the valence band. The HH phases have a fairly decent Seebeck coefficient with moderate electrical conductivity. The performance of thermoelectric materials depends on ZT, defined by ZT=(S²σ/κ)T, where σ is the electrical conductivity, S the Seebeck coefficient, κ the thermal conductivity, and T the absolute temperature. Half-Heusler compounds may be good thermoelectric materials due to their high power factor (S²σ).

The dimensionless thermoelectric figure-of-merit (ZT) of conventional HHs is lower than that of many other state-of-the-art thermoelectric materials. Recently, enhancements in the dimensionless thermoelectric figure-of-merit (ZT) of n-type half-Heusler materials using a nanocomposite approach has been achieved. A peak ZT of 1.0 was achieved at 600-700° C., which is about 25% higher than the previously reported highest value. The materials may be made by ball milling ingots of composition Hf_{0.7}Zr_{0.25}NiSn_{0.99}Sb_{0.01} into nanopowders and hot pressing (e.g., DC hot pressing or without the application of current) the powders into dense bulk samples. The ingots may be formed by arc melting the constituent elements. The ZT enhancement mainly comes from reduction of thermal conductivity due to increased phonon scattering at grain boundaries and crystal defects, and optimization of antimony doping.

By using a nanocomposite half-Heusler material, a greater than 35% ZT improvement from 0.5 to 0.8 in p-type half-Heusler compounds at temperatures above 400° C. has been achieved. Additionally, a 25% improvement in peak ZT, from 0.8 to 1.0 at temperatures above 400° C., in n-type half-Heusler compounds by the same nanocomposite approach has been achieved. The ZT enhancement is not only due to the reduction in the thermal conductivity but also an increase in the power factor. These nanostructured samples may be prepared, for example, by hot pressing a ball milled nanopowder from ingots which are initially made by an arc melting process. The hot pressed, dense bulk samples may be nanostructured with grains having a mean grain size less than 300 nm in which at least 90% of the grains are less than 500 nm in size. In some cases, the grains have a mean size in a range of 10-300 nm, such as a mean size of around 200 nm. Typically, the grains have random orientations. Further, many grains may include 10-50 nm size (e.g., diameter or width) nanodot inclusions within the grains.

Embodiments of the half-Heusler materials may include varying amounts of Hf, Zr, Ti, Co, Ni, Sb, Sn depending on whether the material is n-type or p-type. Other alloying elements such as Pb may also be added. Example p-type materials include, but are not limited to, Co containing and Sb rich/Sn poor Hf_{0.5}Zr_{0.5}CoSb_{0.8}Sn_{0.2}, Hf_{0.3}Zr_{0.7}CoSb_{0.7}Sn_{0.3}, Hf_{0.5}Zr_{0.5}CoSb_{0.8}Sn_{0.2}+1% Pb, Hf_{0.8}Ti_{0.5}CoSb_{0.8}Sn_{0.2}, and Hf_{0.5}Ti_{0.5}CoSb_{0.6}Sn_{0.4}. Example n-type materials include, but are not limited to, Ni containing and Sn rich/Sb poor Hf_{0.7}Zr_{0.25}NiSn_{0.975}Sb_{0.025}, Hf_{0.25}Zr_{0.25}Ti_{0.5}NiSn_{0.994}Sb_{0.006}, Hf_{0.25}Zr_{0.25}NiSn_{0.99}Sb_{0.01} (Ti_{0.30}Hf_{0.35}Zr_{0.35})Ni(Sn_{0.994}Sb_{0.006}), Hf_{0.25}Zr_{0.25}Ti_{0.5}NiSn_{0.99}Sb_{0.01}, Hf_{0.5}Zr_{0.25}Ti_{0.25}NiSn_{0.99}Sb_{0.01} and (Hf,Zr)_{0.5}Ti_{0.5}NiSn_{0.998}Sb_{0.002}.

The ingot may be made by are melting individual elements of the thermoelectric material in the appropriate ratio to form the desired thermoelectric material. Preferably, the individual elements are 99.9% pure. More preferably, the individual elements are 99.99% pure. In some cases, two or more of the individual elements may first be combined into an alloy or compound and the alloy or compound used as one of the starting materials in the arc melting process. Ball milling may result in a nanopowder with nanometer size particles that have a mean size less than 100 nm in which at least 90% of the particles are less than 250 nm in size. In one example, the nanometer size particles have a mean particle size in a range of 5-100 nm.

It has been discovered that the figure of merit of thermoelectric materials improves as the grain size in the thermoelectric material decreases. In one example of a method for fabricating thermoelectric materials, thermoelectric materials with nanometer scale (less than 1 micron) grains are produced, i.e., 95%, such as 100% of the grains have a grain size less than 1 micron. Preferably, the nanometer scale mean grain size is in a range of 10-300 nm. This method may be used to fabricate any thermoelectric material and includes making half-Heusler materials with nanometer scale grains. The method may be used to make both p-type and n-type half-Heusler materials. In one example, the half-Heusler material is n-type and has the formula Hf_{1+δ-x-y}ZrₓTi_{y}NiSn_{1+δ-z}Sb_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}NiSn_{1-z}Sb, where 0≦x≦1.0, 0≦y≦1.0, and 0≦z≦1.0 when δ=0 (i.e., for the stoichiometric material). In another example, the half-Heusler is a p-type material and has the formula Hf_{1+δ-x-y}ZrₓTi_{y}CoSb_{1+δ-z}Sn_{z}, where 0≦x≦1.0, 0≦y≦1.0, 0≦z≦1.0, and −0.1≦δ≦0.1 (to allow for slightly non-stoichiometric material), such as Hf_{1-x-y}ZrₓTi_{y}CoSb_{1-z}Sn_{z}, where 0≦x≦1.0, 0≦y≦1.0, and 0≦z≦1.0 when δ=0 (i.e., for the stoichiometric material).

The preceding description of the disclosed aspects is provided to enable any person skilled in the art to make or use the present invention. Various modifications to these aspects will be readily apparent to those skilled in the art, and the generic principles defined herein may be applied to other aspects without departing from the scope of the invention. Thus, the present invention is not intended to be limited to the aspects shown herein but is to be accorded the widest scope consistent with the principles and novel features disclosed herein.

What is claimed is:

1. A thermoelectric power generator module, comprising:
a plurality of thermoelectric elements, each comprising a first side adapted to be at a first temperature and a second side adapted to be at a second temperature different than the first temperature when the module is in use; and
a flexible connector that electrically connects the first sides of at least two thermoelectric elements.

2. The thermoelectric power generator module of claim 1, wherein the flexible connector is adapted to provide thermal strain relief and vibration damping to the thermoelectric elements.

3. The thermoelectric power generator module of claim 1, wherein each of the plurality of thermoelectric elements comprises a thermoelectric leg.

4. The thermoelectric power generator module of claim 3, wherein the flexible connector comprises an electrically and thermally conductive material.

5. The thermoelectric power generator module of claim 4, wherein the flexible connector comprises a mesh, a felt or a foam.

6. The thermoelectric power generator module of claim 4, wherein the flexible connector comprises a plurality of wires extending between a connector base and an end of the thermoelectric leg.

7. The thermoelectric power generator module of claim 4, wherein the flexible connector comprises at least one angled connector element that extends from a first end secured to a connector base to a second end that is thermally and electrically coupled to an end of the thermoelectric leg.

8. The thermoelectric power generator module of claim 4, wherein the flexible connector comprises at least one curved connector member secured to a connector base and thermally and electrically coupled to an end of the thermoelectric leg.

9. The thermoelectric power generator module of claim 8, wherein the at least one curved connector member comprises at least one hollow shell.

10. The thermoelectric power generator module of claim 9, wherein the at least one hollow shell comprises one hollow shell supporting a respective one of the plurality of thermoelectric elements.

11. The thermoelectric power generator module of claim 9, wherein the at least one hollow shell comprises a plurality of hollow shells supporting one of the plurality of thermoelectric elements.

12. The thermoelectric power generator of claim 4, wherein the flexible connector comprises a bent portion that provides an elastically deformable region that allows a pair of the thermoelectric legs to be displaced relative to one another while maintaining a thermal and electrical connection between the thermoelectric legs.

13. A flexible connector for a thermoelectric power generator module that is configured to electrically couple at least two thermoelectric elements so as to provide strain relief and vibration damping during operation of the module.

14. A method of fabricating a thermoelectric power generator module, comprising:
connecting a first thermoelectric element to a flexible connector, and
connecting a second thermoelectric element to the flexible connector to electrically connect the first and second thermoelectric elements.

15. The method of claim 14, wherein the flexible connector provides thermal strain relief and vibration damping to the thermoelectric elements.

16. The method of claim 14, wherein the first thermoelectric element comprises a thermoelectric leg of a first conductivity type and the second thermoelectric element comprises a thermoelectric leg of a second conductivity type.

17. The method of claim 14, wherein the flexible connector comprises an electrically and thermally conductive material.

18. The method of claim 17, wherein the flexible connector comprises at least one deformable region that allows the first thermoelectric element to be displaced relative to the second thermoelectric element while maintaining a thermal and electrical connection between the flexible connector and the first and second thermoelectric elements.
